(19) United States
(12) Patent Application Publication
(10) Pub. No.: US 2026/0122809 A1
(43) Pub. Date: Apr. 30, 2026

(54) MONITOR STAND AND MONITOR APPARATUS THEREOF

(71) Applicant: BENQ CORPORATION, Taipei City (TW)

(72) Inventors: Meng-Yang Hsiao, Taipei City (TW); Shih-Ho Chen, Taipei City (TW); Jen-Hsiang Chan, Taipei City (TW)

(73) Assignee: BENQ CORPORATION, Taipei City (TW)

(21) Appl. No.: 19/262,152

(22) Filed: Jul. 8, 2025

(30) Foreign Application Priority Data
Oct. 24, 2024 (TW) 113140495

(51) Int. Cl. H05K 5/02; F16M 11/08

(52) U.S. Cl. CPC H05K 5/0234; F16M 11/08; F16M 2200/066

(57) ABSTRACT

A monitor stand is suitable for connecting to a display monitor and includes a support column, a rear cantilever, a front cantilever, and a limiting slot structure. The rear cantilever is pivoted to the support column and has a first pivot end portion. The front cantilever is pivoted to the display monitor and has a second pivot end portion. The limiting slot structure is disposed on the first pivot end portion or the second pivot end portion. A connection line between a first pivot point of the front cantilever and the display monitor and a third pivot point of the rear cantilever and the support column does not pass through a second pivot point of the rear cantilever and the front cantilever.

### BACKGROUND OF THE INVENTION

### 1. FIELD OF THE INVENTION

The present invention relates to a monitor stand and a monitor apparatus thereof, and more specifically, to a monitor stand forming a limiting slot structure at a position where a front cantilever is pivoted to a rear cantilever for preventing a connection line between a first pivot point of the front cantilever and a display monitor and a third pivot point of the rear cantilever and a support column from passing through a second pivot point of the rear cantilever and the front cantilever and a monitor apparatus thereof.

### 2. DESCRIPTION OF THE PRIOR ART

With advancements in technology, a display monitor (e.g., an LCD monitor) has become thinner, lighter, and more portable, and is widely used in daily life. Due to the portability of the display monitor, a user can mount the display monitor on a monitor stand compatible with international VESA standards for use in various scenarios. Furthermore, the monitor stand usually adopts a pivoted cantilever design, allowing front and rear cantilevers to fold together or extend straight. This design enables the user to quickly and effortlessly move the display monitor closer or farther to achieve a suitable viewing or operating distance.

However, the aforementioned design usually causes the problem that a disassembly and assembly mechanism between the display monitor and the monitor stand is complicated and difficult to operate and the display monitor and the monitor stand are not easy to align and assemble, thereby greatly reducing the convenience and reliability of the monitor stand in assembly and disassembly. Additionally, when the front and rear cantilevers are fully extended into a straight line and the user wants to push the display monitor away, the front and rear cantilevers usually get stuck and are difficult to fold since there is only a vertical force exerted upon a pivot point of the front and rear cantilevers without a lateral force. This may cause the user much inconvenience in monitor distance adjustment and also create an uncomfortable user experience.

### SUMMARY OF THE INVENTION

Thus, one purpose of the present invention is to provide a monitor stand forming a limiting slot structure at a position where a front cantilever is pivoted to a rear cantilever for preventing a connection line between a first pivot point of the front cantilever and a display monitor and a third pivot point of the rear cantilever and a support column from passing through a second pivot point of the rear cantilever and the front cantilever and a monitor apparatus thereof, to solve the aforesaid problems.

According to an embodiment, a monitor stand of the present invention is suitable for connecting to a display monitor. The monitor stand includes a support column, a rear cantilever, a front cantilever, and a limiting slot structure. The rear cantilever is pivotally connected to the support column and has a first pivot end portion. The front cantilever is pivotally connected to the display monitor and has a second pivot end portion. The limiting slot structure is disposed on the first pivot end portion or the second pivot end portion. A connection line between a first pivot point of the front cantilever and the display monitor and a third pivot point of the rear cantilever and the support column does not pass through a second pivot point of the rear cantilever and the front cantilever.

According to another embodiment, a monitor apparatus of the present invention includes a display monitor and a monitor stand. The monitor stand is connected to the display monitor. The monitor stand includes a support column, a rear cantilever, a front cantilever, and a limiting slot structure. The rear cantilever is pivotally connected to the support column and has a first pivot end portion. The front cantilever is pivotally connected to the display monitor and has a second pivot end portion. The limiting slot structure is disposed on the first pivot end portion or the second pivot end portion. A connection line between a first pivot point of the front cantilever and the display monitor and a third pivot point of the rear cantilever and the support column does not pass through a second pivot point of the rear cantilever and the front cantilever.

In summary, compared with the prior art adopting the design in which the front and rear cantilevers are pivotally connected to fold together or unfold in a straight line, the present invention adopt the aforesaid limiting slot design to achieve the cantilever-limiting effect of ensuring that the three pivot points of the front and rear cantilevers are not collinear. Furthermore, the present invention adopts the aforesaid pillar design in which the protruding pillar is detachably inserted into the recessed structure via alignment and engagement between the limiting slot structure and the pin member, to generate the quick assembly and disassembly effect. In such a manner, the present invention can effectively solve the prior art problem that the front and rear cantilevers get stuck in a straight-line configuration and fail to fold. Furthermore, the present invention also solves the prior art problem that the disassembly and assembly mechanism between the display monitor and the monitor stand is complicated and the display monitor and the monitor stand are not easy to align and assemble. Thus, the present invention can greatly improve operational reliability of the monitor stand in monitor distance adjustment, provide a smooth operating experience, and enhance convenience of the monitor stand in assembly and disassembly.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a partial exploded diagram of a monitor apparatus according to one embodiment of the present invention.

FIG. 2 is a partial cross-sectional diagram of the monitor apparatus in FIG. 1 along a cross-sectional line A-A when a protruding pillar of a front cantilever is inserted into a recessed structure of a rear cantilever.

FIG. 3 is a top view of the monitor apparatus in FIG. 1 when the protruding pillar is inserted into the recessed structure.

FIG. 4 is a partial exploded diagram of the monitor apparatus in FIG. 1 when the front cantilever is connected to the display monitor and another display monitor via an adapter cantilever.

FIG. 5 is a partial cross-sectional diagram of a monitor apparatus according to another embodiment of the present invention.

### DETAILED DESCRIPTION

The present invention will now be described more specifically with reference to the following embodiments and the accompanying drawings. Other advantages and effects of the present invention can be easily understood by a person ordinarily skilled in the art in view of the detailed descriptions and the accompanying drawings. The present invention can be implemented or applied to other different embodiments. Certain aspects of the present invention are not limited by the particular details of the examples illustrated herein. Without departing from the spirit and scope of the present invention, the present invention will have other modifications and changes. It should be understood that the appended drawings are not necessarily drawn to the scale and configuration of each component (e.g., structural designs and sizes of a limiting slot and a pin, a column connection design, and an adapter cantilever design) in the drawings is merely illustrative, not presenting an actual condition of the embodiments.

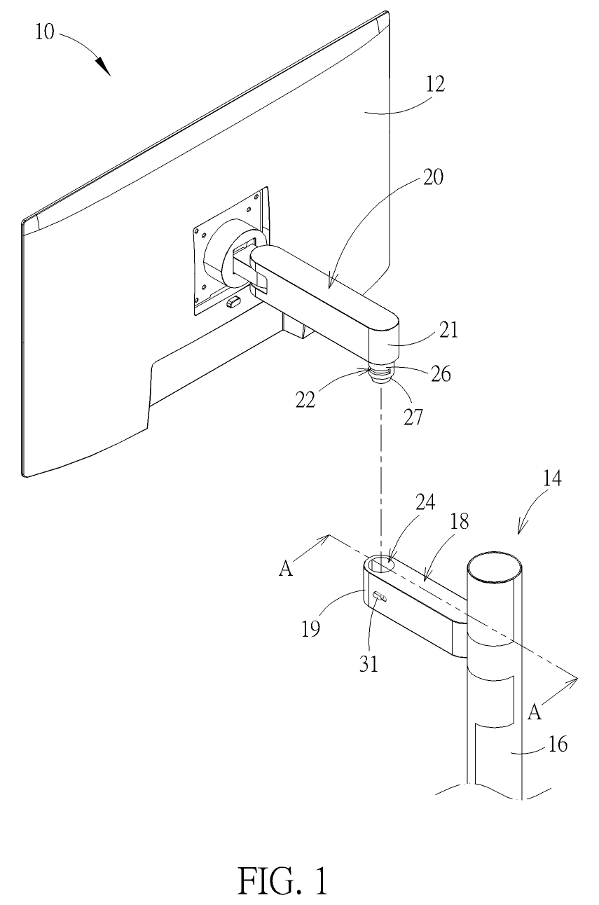

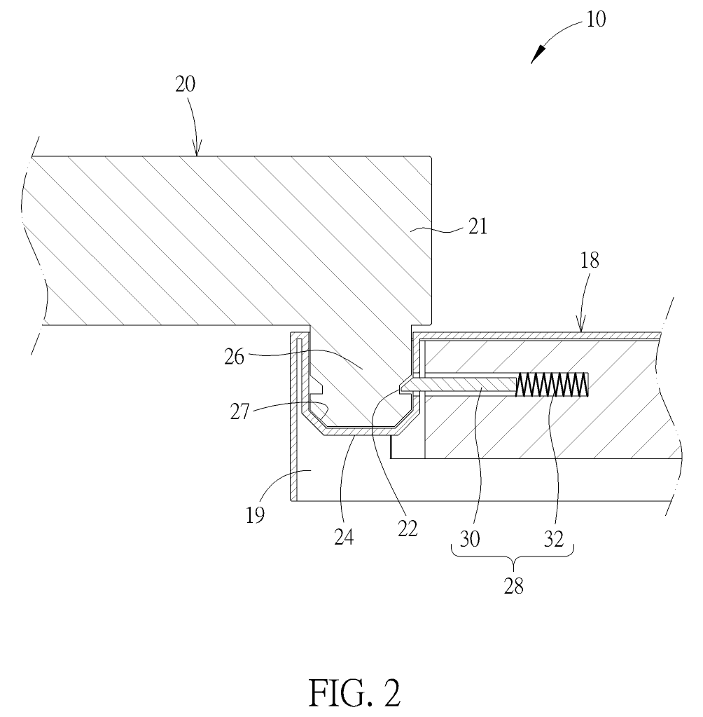

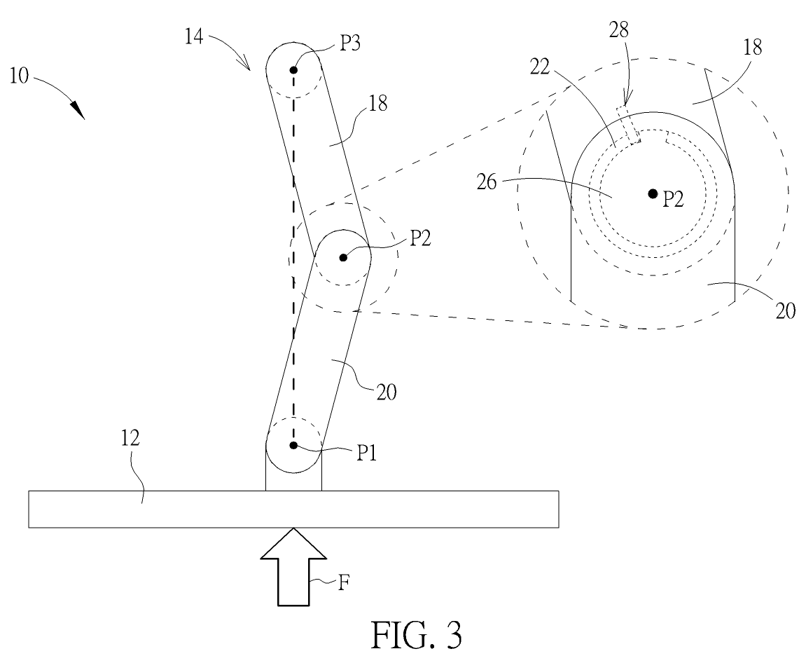

Please refer to FIG. 1, FIG. 2 and FIG. 3. FIG. 1 is a partial exploded diagram of a monitor apparatus 10 according to one embodiment of the present invention. FIG. 2 is a partial cross-sectional diagram of the monitor apparatus 10 in FIG. 1 along a cross-sectional line A-A when a protruding pillar 26 of a front cantilever 20 is inserted into a recessed structure 24 of a rear cantilever 18. FIG. 3 is a top view of the monitor apparatus 10 in FIG. 1 when the protruding pillar 26 is inserted into the recessed structure 24. For clearly showing a folding design of the rear cantilever 18 and the front cantilever 20 of the monitor apparatus 10, the monitor apparatus 10 is depicted by simplified outlines in FIG. 3. As shown in FIG. 1, FIG. 2 and FIG. 3, the monitor apparatus 10 could be preferably a monitor device with a support function. The monitor apparatus 10 includes a display monitor 12 (e.g., an LCD monitor, but not limited thereto) and a monitor stand 14. The monitor stand 14 includes a support column 16, the rear cantilever 18, the front cantilever 20, and a limiting slot structure 22. The display monitor 12 could be preferably suspended above a support surface (e.g., a desktop) by being connected to the support column 16 vertically fixed on the support surface. However, the present invention is not limited to the aforesaid upright support design. That is, the present invention could adopt other column connection design, such as securing the support column 16 to a ceiling to suspend the display monitor 12 below the ceiling or mounting the support column 16 on a vertical wall to hang the display monitor 12 laterally from the vertical wall, and the related description could be reasoned by analogy according to the following description and omitted herein.

As shown in FIG. 1, FIG. 2 and FIG. 3, the rear cantilever 18 is pivotally connected to the support column 16 and has a first pivot end portion 19. The front cantilever 20 is pivotally connected to the display monitor 12 (e.g., via a VESA-standard mounting plate, wherein the related description is commonly seen in the prior art and omitted herein) and has a second pivot end portion 21 pivotally connected to the first pivot end portion 19. In this embodiment, the limiting slot structure 22 could be preferably disposed on the second pivot end portion 21 (but not limited thereto, meaning that the limiting slot structure 22 could be disposed on the first pivot end portion 19 in another embodiment, and the related description could be reasoned by analogy according to the following description and omitted herein). As such, via folding or extending of the rear cantilever 18 and the front cantilever 20, a user can quickly and effortlessly move the display monitor 12 closer or farther for achieving a suitable viewing or operating distance. Additionally, the limiting slot structure 22 can ensure that a connection line between a first pivot point P1 of the front cantilever 20 and the display monitor 12 and a third pivot point P3 of the rear cantilever 18 and the support column 16 does not pass through a second pivot point P2 of the rear cantilever 18 and the front cantilever 20 (as shown in FIG. 3). This design effectively prevents the rear cantilever 18 and the front cantilever 20 from forming a fully straightened alignment.

More specifically, as shown in FIG. 1, FIG. 2 and FIG. 3, the monitor stand 14 could further include a recessed structure 24, a protruding pillar 26, and a pin member 28. The recessed structure 24 is disposed on the first pivot end portion 19. The protruding pillar 26 is disposed on the second pivot end portion 21 and is rotatably inserted into the recessed structure 24. The limiting slot structure 22 is formed on the protruding pillar 26, and the pin member 28 is disposed in the recessed structure 24. When the protruding pillar 26 is inserted into the recessed structure 24, the pin member 28 is inserted into the limiting slot structure 22, so as to make the front cantilever 20 detachably pivoted to the rear cantilever 18. This design allows the user to quickly and accurately complete the monitor stand assembly operation of the monitor apparatus 10 via alignment of the protruding pillar 26 and the recessed structure 24. The limiting slot structure 22 could be formed as an arc-shaped slot along a periphery of the protruding pillar 26 (as shown in FIG. 3). A central angle of the limiting slot structure 22 relative to the protruding pillar 26 is less than 360 degrees, so as to ensure that the connection line between the first pivot point P1 and the third pivot point P3 does not pass through the second pivot point P2.

In other words, as shown in FIG. 3, when the front cantilever 20 and the rear cantilever 18 are fully extended, via the design in which the pin member 28 is inserted into the limiting slot structure 22 and the central angle of the limiting slot structure 22 is less than 360 degrees, an angle between the front cantilever 20 and the rear cantilever 18 is less than 180 degrees, so as to prevent the rear cantilever 18 and the front cantilever 20 from unfolding in a completely straight line. For example, in this embodiment, a maximum unfolded angle between the front cantilever 20 and the rear cantilever 18 can be designed to be 170 degrees. This configuration generates a lateral force (approximately 8.8% of a vertical force F) when the vertical force F is applied to the display monitor 12, allowing the front cantilever 20 to fold smoothly relative to the rear cantilever 18. However, the present invention is not limited thereto, meaning that the limiting angle depends on the actual application requirements of the monitor apparatus 10. For example, in another embodiment, the maximum unfolded angle between the front cantilever 20 and the rear cantilever 18 could be designed to be 160 degrees for generating a lateral force of approximately 17.6% of the vertical force F, or could be designed to be 150 degrees for generating a lateral force of approximately 26.8% of the vertical force F.

To be noted, the design in which the protruding pillar is inserted into the recessed structure is not limited to the aforesaid embodiment. Alternatively, the protruding pillar 26 could be disposed on the first pivot end portion 19 and rotatably inserted into the recessed structure 24 formed on the second pivot end portion 21 in another embodiment, and the related description could be reasoned by analogy according to FIG. 1 and FIG. 2 and omitted herein.

In practical applications, the present invention could adopt an elastic pin design. For example, as shown in FIG. 2, the pin member 28 could include a pin 30 and a spring 32. The pin 30 is retractably inserted into the recessed structure 24, and the spring 32 is connected to the pin 30. When the protruding pillar 26 is inserted into the recessed structure 24 to make the limiting slot structure 22 aligned with the pin 30, the spring 32 drives the pin 30 to extend into the limiting slot structure 22, so as to detachably pivot the front cantilever 20 to the rear cantilever 18 and prevent the connection line between the first pivot point P1 and the third pivot point P3 from passing through the second pivot point P2. Furthermore, to enhance the operational convenience and assembly reliability of the monitor stand 14, as shown in FIGS. 1 and 2, a chamfered structure 27 could be formed on the protruding pillar 26 at a position corresponding to the recessed structure 24 for guiding the protruding pillar 26 to be inserted into the recessed structure 24 smoothly. As such, quick and precise alignment and insertion of the protruding pillar 26 into the recessed structure 24 can be ensured. Additionally, as shown in FIG. 1, the pin 30 could have an operating component 31 (e.g., a push-button structure, but not limited thereto) protruding from the rear cantilever 18 with the recessed structure 24 slidably. When the user wants to perform a quick-release operation to detach the front cantilever 20 from the rear cantilever 18, the user could just push the operating component 31 to slide the pin 30 out of the limiting slot structure 22, thereby disengaging the protruding pillar 26 from the recessed structure 24. This allows the front cantilever 20, which is connected to the display monitor 12, to be quickly detached from the rear cantilever 18 for subsequent replacement, repair, or related operations.

In summary, compared with the prior art adopting the design in which the front and rear cantilevers are pivotally connected to fold together or unfold in a straight line, the present invention adopt the aforesaid limiting slot design to achieve the cantilever-limiting effect of ensuring that the three pivot points of the front and rear cantilevers are not collinear. Furthermore, the present invention adopts the aforesaid pillar design in which the protruding pillar is detachably inserted into the recessed structure via alignment and engagement between the limiting slot structure and the pin member, to generate the quick assembly and disassembly effect. In such a manner, the present invention can effectively solve the prior art problem that the front and rear cantilevers get stuck in a straight-line configuration and fail to fold. Furthermore, the present invention also solves the prior art problem that the disassembly and assembly mechanism between the display monitor and the monitor stand is complicated and the display monitor and the monitor stand are not easy to align and assemble. Thus, the present invention can greatly improve operational reliability of the monitor stand in monitor distance adjustment, provide a smooth operating experience, and enhance convenience of the monitor stand in assembly and disassembly.

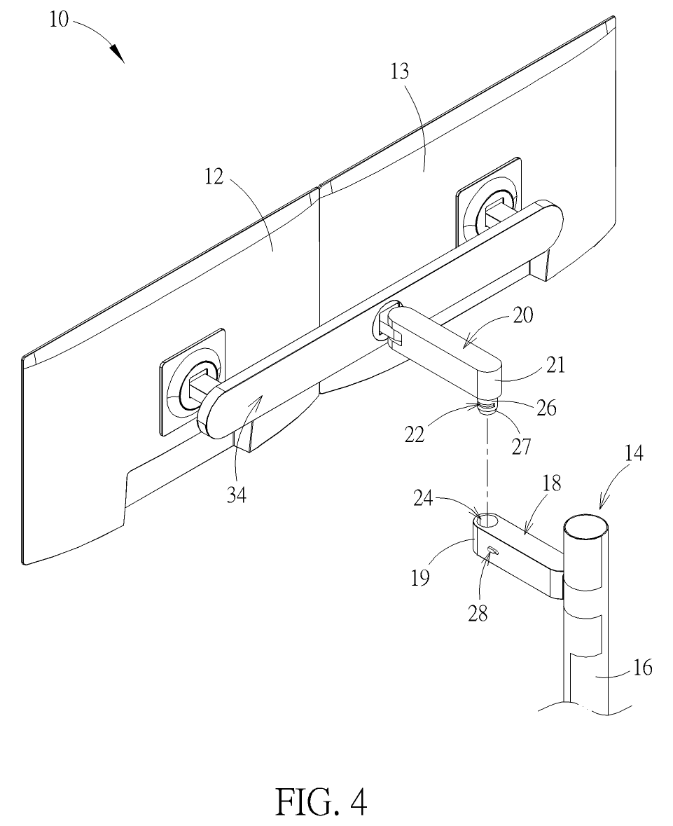

It should be mentioned that the present invention is not limited to the single-monitor configuration described in the aforesaid embodiment. The present invention could also adopt a multi-monitor configuration (e.g., a dual-monitor configuration, but not limited thereto, meaning that the number of monitors depends on the actual application of the monitor apparatus 10 and the adapter cantilever design). For example, please refer to FIG. 4, which is a partial exploded diagram of the monitor apparatus 10 in FIG. 1 when the front cantilever 20 is connected to the display monitor 12 and another display monitor 13 via an adapter cantilever 34. Components both mentioned in this embodiment and the aforesaid embodiments represent components with similar structures or functions, and the related description is omitted herein. As shown in FIG. 4, the monitor apparatus 10 could include the display monitor 12, the monitor stand 14, and the another display monitor 13. The monitor stand 14 includes the support column 16, the rear cantilever 18, the front cantilever 20, the limiting slot structure 22, the recessed structure 24, the protruding pillar 26, the pin member 28, and the adapter cantilever 34. The adapter cantilever 34 could be connected to the display monitor 12 and the another display monitor 13 (e.g., via VESA-standard mounting plates, but not limited thereto) and is pivotally connected to the front cantilever 20. This allows the display monitor 12 and the another display monitor 13 to pivot relative to the front cantilever 20 via the adapter cantilever 34, enabling the user to perform subsequent dual-monitor adjustments (e.g., pushing the display monitor 12 and the another display monitor 13 farther or closer to achieve a suitable viewing or operating distance).

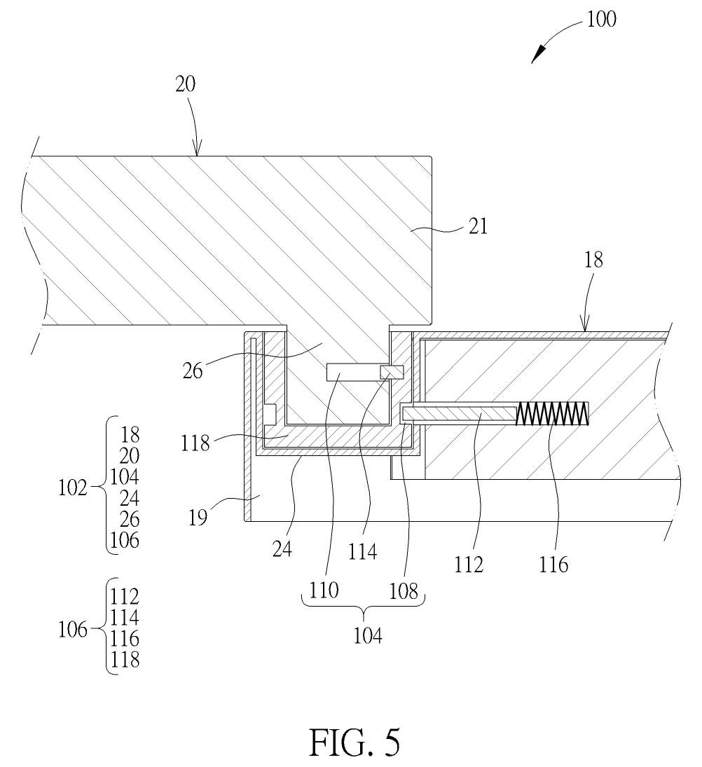

Furthermore, the limiting slot structure of the present invention is not limited to the aforementioned embodiments, meaning that the present invention could adopt a limiting sleeve design. For example, please refer to FIG. 5, which is a partial cross-sectional diagram of a monitor apparatus 100 according to another embodiment of the present invention. Components both mentioned in this embodiment and the aforesaid embodiments represent components with similar structures or functions, and the related description is omitted herein. As shown in FIG. 5, the monitor apparatus 100 could include the display monitor 12 (not shown in the figure) and a monitor stand 102. The monitor stand 102 includes the support column 16 (not shown in the figure), the rear cantilever 18, the front cantilever 20, the recessed structure 24, the protruding pillar 26, a limiting slot structure 104, and a pin member 106. The limiting slot structure 104 includes a positioning slot 108 and a limiting slot 110. The pin member 106 includes a first pin 112, a second pin 114, a spring 116, and a limiting sleeve 118. The positioning slot 108 is formed on an outer side of the limiting sleeve 118, and the second pin 114 is disposed on an inner side of the limiting sleeve 118. The limiting slot 110 could be preferably formed as an arc-shaped slot along a periphery of the protruding pillar 26, and a central angle of the limiting slot 110 relative to the protruding pillar 26 is less than 360 degrees. The first pin 112 is retractably inserted into the recessed structure 24, and the spring 116 is connected to the first pin 112. Accordingly, when the protruding pillar 26 is inserted into the limiting sleeve 118 and the limiting sleeve 118 is inserted into the recessed structure 24 to align the positioning slot 108 with the first pin 112, the spring 116 drives the first pin 112 to extend into the positioning slot 108. This allows the front cantilever 20 to be detachably connected to the rear cantilever 18. Simultaneously, the second pin 114 is inserted into the limiting slot 110, so as to ensure that the connection line between the first pivot point P1 of the front cantilever 20 and the display monitor 12 and the third pivot point P3 of the rear cantilever 18 and the support column 16 does not pass through the second pivot point P2 of the rear cantilever 18 and the front cantilever 20 (not shown in FIG. 5, but the related description could be reasoned by analogy according to FIG. 3). As for other derivative designs in this embodiment (e.g., the operating component design for retracting the first pin 112 from the limiting slot 110 and the chamfered structural design for guiding insertion of the limiting sleeve 118 into the recessed structure 24), the related description could be reasoned by analogy according to the aforesaid embodiments and omitted herein.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A monitor stand suitable for connecting to a display monitor, the monitor stand comprising:
a support column;
a rear cantilever pivotally connected to the support column and having a first pivot end portion;
a front cantilever pivotally connected to the display monitor and having a second pivot end portion; and
a limiting slot structure disposed on the first pivot end portion or the second pivot end portion, wherein a connection line between a first pivot point of the front cantilever and the display monitor and a third pivot point of the rear cantilever and the support column does not pass through a second pivot point of the rear cantilever and the front cantilever.

2. The monitor stand of claim 1, wherein the monitor stand further comprises:
a recessed structure disposed on one of the first pivot end portion and the second pivot end portion;
a protruding pillar disposed on the other of the first pivot end portion and the second pivot end portion and rotatably inserted into the recessed structure, wherein the limiting slot structure is formed on the protruding pillar; and
a pin member disposed in the recessed structure and inserted into the limiting slot structure when the protruding pillar is inserted into the recessed structure, to make the front cantilever detachably pivoted to the rear cantilever and prevent the connection line between the first pivot point and the third pivot point from passing through the second pivot point.

3. The monitor stand of claim 2, wherein the pin member comprises:
a pin retractably inserted into the recessed structure; and
a spring connected to the pin for driving the pin to extend into the limiting slot structure when the protruding pillar is inserted into the recessed structure and the limiting slot structure is aligned with the pin.

4. The monitor stand of claim 3, wherein the pin has an operating component protruding from the rear cantilever with the recessed structure or the front cantilever with the recessed structure slidably, and the pin retracts from the limiting slot structure with sliding of the operating component to release engagement between the protruding pillar and the recessed structure.

5. The monitor stand of claim 2, wherein the limiting slot structure is formed as an arc-shaped limiting slot along a periphery of the protruding pillar, and a central angle of the arc-shaped limiting slot relative to the protruding pillar is less than 360 degrees.

6. The monitor stand of claim 2, wherein a chamfered structure is formed on the protruding pillar at a position corresponding to the recessed structure for guiding insertion of the protruding pillar into the recessed structure.

7. The monitor stand of claim 2, wherein the limiting slot structure comprises a positioning slot and a limiting slot, and the pin member comprises a first pin, a second pin, a spring, and a limiting sleeve, the positioning slot is formed on an outer side of the limiting sleeve, the second pin is disposed on an inner side of the limiting sleeve, the limiting slot is formed on the protruding pillar, the first pin is retractably disposed within the recessed structure, and the spring is connected to the first pin;
when the protruding pillar is inserted into the limiting sleeve and the limiting sleeve is inserted into the recessed structure to align the positioning slot with the first pin, the spring drives the first pin to extend into the positioning slot to make the front cantilever detachably pivoted to the rear cantilever, and the second pin is inserted into the limiting slot to prevent the connection line between the first pivot point and the third pivot point from passing through the second pivot point.

8. The monitor stand of claim 7, wherein the first pin includes an operating component protruding from the rear cantilever with the recessed structure or the front cantilever with the recessed structure slidably, and the first pin retracts from the positioning slot with sliding of the operating component to release engagement between the limiting sleeve and the recessed structure.

9. The monitor stand of claim 7, wherein the limiting slot structure is formed as an arc-shaped limiting slot along a periphery of the protruding pillar, and a central angle of the arc-shaped limiting slot relative to the protruding pillar is less than 360 degrees.

10. The monitor stand of claim 7, wherein a chamfered structure is formed on the limiting sleeve at a position corresponding to the recessed structure for guiding insertion of the limiting sleeve into the recessed structure.

11. The monitor stand of claim 1, wherein the monitor stand further comprises:
an adapter cantilever connected to the display monitor and another display monitor and pivotally connected to the front cantilever, to make the display monitor and the another display monitor pivotable relative to the front cantilever via the adapter cantilever.

12. A monitor apparatus comprising:
a display monitor; and
a monitor stand connected to the display monitor, the monitor stand comprising:
a support column;
a rear cantilever pivotally connected to the support column and having a first pivot end portion;
a front cantilever pivotally connected to the display monitor and having a second pivot end portion; and
a limiting slot structure disposed on the first pivot end portion or the second pivot end portion, wherein a connection line between a first pivot point of the front cantilever and the display monitor and a third pivot point of the rear cantilever and the support column does not pass through a second pivot point of the rear cantilever and the front cantilever.

13. The monitor apparatus of claim 12, wherein the monitor stand further comprises:
a recessed structure disposed on one of the first pivot end portion and the second pivot end portion;
a protruding pillar disposed on the other of the first pivot end portion and the second pivot end portion and rotatably inserted into the recessed structure, wherein the limiting slot structure is formed on the protruding pillar; and
a pin member disposed in the recessed structure and inserted into the limiting slot structure when the protruding pillar is inserted into the recessed structure, to make the front cantilever detachably pivoted to the rear cantilever and prevent the connection line between the first pivot point and the third pivot point from passing through the second pivot point.

14. The monitor apparatus of claim 13, wherein the pin member comprises:
a pin retractably inserted into the recessed structure; and
a spring connected to the pin for driving the pin to extend into the limiting slot structure when the protruding pillar is inserted into the recessed structure and the limiting slot structure is aligned with the pin.

15. The monitor apparatus of claim 14, wherein the pin has an operating component protruding from the rear cantilever with the recessed structure or the front cantilever with the recessed structure slidably, and the pin retracts from the limiting slot structure with sliding of the operating component to release engagement between the protruding pillar and the recessed structure.

16. The monitor apparatus of claim 13, wherein the limiting slot structure is formed as an arc-shaped limiting slot along a periphery of the protruding pillar, and a central angle of the arc-shaped limiting slot relative to the protruding pillar is less than 360 degrees.

17. The monitor apparatus of claim 13, wherein a chamfered structure is formed on the protruding pillar at a position corresponding to the recessed structure for guiding insertion of the protruding pillar into the recessed structure.

18. The monitor apparatus of claim 13, wherein the limiting slot structure comprises a positioning slot and a limiting slot, and the pin member comprises a first pin, a second pin, a spring, and a limiting sleeve, the positioning slot is formed on an outer side of the limiting sleeve, the second pin is disposed on an inner side of the limiting sleeve, the limiting slot is formed on the protruding pillar, the first pin is retractably disposed within the recessed structure, and the spring is connected to the first pin;
when the protruding pillar is inserted into the limiting sleeve and the limiting sleeve is inserted into the recessed structure to align the positioning slot with the first pin, the spring drives the first pin to extend into the positioning slot to make the front cantilever detachably pivoted to the rear cantilever, and the second pin is inserted into the limiting slot to prevent the connection line between the first pivot point and the third pivot point from passing through the second pivot point.

19. The monitor apparatus of claim 18, wherein the first pin includes an operating component protruding from the rear cantilever with the recessed structure or the front cantilever with the recessed structure slidably, and the first pin retracts from the positioning slot with sliding of the operating component to release engagement between the limiting sleeve and the recessed structure.

20. The monitor apparatus of claim 18, wherein the limiting slot structure is formed as an arc-shaped limiting slot along a periphery of the protruding pillar, and a central angle of the arc-shaped limiting slot relative to the protruding pillar is less than 360 degrees.
